(19) United States
(12) Patent Application Publication
(10) Pub. No.: US 2026/0039292 A1
(43) Pub. Date: Feb. 5, 2026

(54) TRANSFORMER COMMUNICATION SYSTEM WITH RINGING SUPPRESSION

(71) Applicant: Texas Instruments Incorporated, Dallas, TX (US)

(72) Inventors: Aman Gupta, MOHALI (IN); Kumar Anurag Shrivastava, BANGALORE (IN); Upasana Bhattacharya, Bangalore (IN)

(21) Appl. No.: 18/790,169

(22) Filed: Jul. 31, 2024

(51) Int. Cl. H03K 17/687; H03K 19/20

(52) U.S. Cl. CPC H03K 17/687; H03K 19/20

(57) ABSTRACT

In described examples, an integrated circuit (IC) includes a differential to single ended (DSE) circuit, and first, second, third, and fourth transistors. A control terminal of the first transistor is coupled to a first output of the DSE circuit. A control terminal of the second transistor is coupled to a second output of the DSE circuit. A first terminal of the third transistor is coupled to a first terminal of the first transistor and a control terminal of the third transistor is coupled to a first terminal of the second transistor. A first terminal of the fourth transistor is coupled to the first terminal of the second transistor, and a control terminal of the fourth transistor is coupled to the first terminal of the first transistor.

### TECHNICAL FIELD

This application relates generally to systems for communicating data across a transformer, and more particularly to a receiver circuit for suppressing ringing in a transformer communication system.

### BACKGROUND

Transformers are used in various applications, such as Ethernet transceivers, to enable high efficiency, low power communications at data rates over 100 megabits per second. As data rates increase, device characteristics such as relatively small parasitic capacitances of transmitter side (primary side) transistors can become increasingly important to overall system performance. In some examples, nonlinearities introduced on the transmitter side can cause signal interpretation errors on the receiver side (secondary side).

### SUMMARY

In described examples, an integrated circuit (IC) includes a differential to single ended (DSE) circuit, and first, second, third, and fourth transistors. A control terminal of the first transistor is coupled to a first output of the DSE circuit. A control terminal of the second transistor is coupled to a second output of the DSE circuit. A first terminal of the third transistor is coupled to a first terminal of the first transistor and a control terminal of the third transistor is coupled to a first terminal of the second transistor. A first terminal of the fourth transistor is coupled to the first terminal of the second transistor, and a control terminal of the fourth transistor is coupled to the first terminal of the first transistor.

In described examples, a circuit includes first, second, third, fourth, fifth, and sixth transistors, and first and second inverters. The control terminal of the third transistor is coupled to the first terminal of the first transistor. The control terminal of the fourth transistor is coupled to the first terminal of the second transistor. The control terminal of the fifth transistor is coupled to the first terminal of the fourth transistor. The control terminal of the sixth transistor is coupled to the first terminal of the third transistor. The input of the first inverter coupled to the first terminal of the third transistor 406 and the first terminal of the fifth transistor. The input of the second inverter is coupled to the first terminal of the fourth transistor and the first terminal of the sixth transistor.

In described examples, an apparatus includes a transformer with primary and secondary windings and an isolation barrier, a transmitter, and a receiver. The receiver includes a differential to single ended (DSE) circuit, first, second, third, and fourth transistors, first and second inverters, and first and second capacitors. The transmitter is coupled to the primary winding. The receiver is coupled to the secondary winding. The first input of the DSE circuit is coupled to the first terminal of the secondary winding, and the second input of the DSE circuit is coupled to the second terminal of the secondary winding. The control terminal of the first transistor is coupled to the first output of the DSE circuit. The control terminal of the second transistor is coupled to the second output of the DSE circuit. The input of the first inverter is coupled to the first terminal of the first transistor and the first terminal of the third transistor. The input of the second inverter is coupled to the first terminal of the second transistor and the first terminal of the fourth transistor. The first terminal of the first capacitor is coupled to the output of the first inverter and the control terminal of the fourth transistor. The first terminal of the second capacitor is coupled to the output of the second inverter and the control terminal of the third transistor.

### BRIEF DESCRIPTION OF THE DRAWINGS

FIG. 1 is a functional block and circuit diagram of an example transceiver system for communicating across a transformer.

FIG. 2A is a set of graphs of example ideal signals of the transceiver system of FIG. 1.

FIG. 2B is a set of graphs of voltage against time for a transmitted signal and a received signal according to the transceiver system of FIG. 1.

FIG. 3 is a functional block diagram of an example of the amplify and sense circuit of FIG. 1.

FIG. 4A is a circuit diagram of an example of the differential to single ended circuit of FIG. 3.

FIG. 4B is a circuit diagram of an example of the analog to digital circuit, buffer circuit, pull-down circuit, and output circuit of FIG. 3.

FIG. 5 is a circuit diagram of an example of the pull-down circuit of FIGS. 3 and 4.

FIG. 6 is a functional block diagram of the output circuit of FIGS. 3 and 4.

FIG. 7 is a set of graphs of voltage against time for various signals of the receiver of FIGS. 1 and 3-6.

### DETAILED DESCRIPTION

In a system for transmitting data from a primary/transmitter side to a secondary/receiver side of a transformer, parasitic capacitances of primary side control switches can cause ringing in the transmitted signal. Such ringing can cause spurious voltage peaks in the transmitted signal following the transmitted data-indicating voltage peak. Spurious voltage peaks can result in false detection of data bits. A logic value corresponding to a transmitted data bit is a first logic value (a one or a zero), and the other logic value is a second logic value (respectively, a zero or a one). A signal portion corresponding to the data-indicating voltage peak arrives at the receiver prior to a signal portion corresponding to the spurious voltage peaks. In an example system, a pull-down circuit in the receiver, activated responsive to the data-indicating voltage peak, can be used to selectively tie an output line providing the second logic value to ground, suppressing false data detection.

Metal-oxide-semiconductor field-effect transistors (MOSFETS) are numbered as M[channel type][number], where the number increases for each differing transistor of a same channel type. Channel types include n-channel MOSFETS (NMOS) and p-channel MOSFETS (PMOS). The channel type for each transistor is only an example, and other examples may substitute another transistor of a different type for any illustrated transistor. Also, the same reference numbers or other reference designators are used in the drawings to designate features that are related structurally and/or functionally.

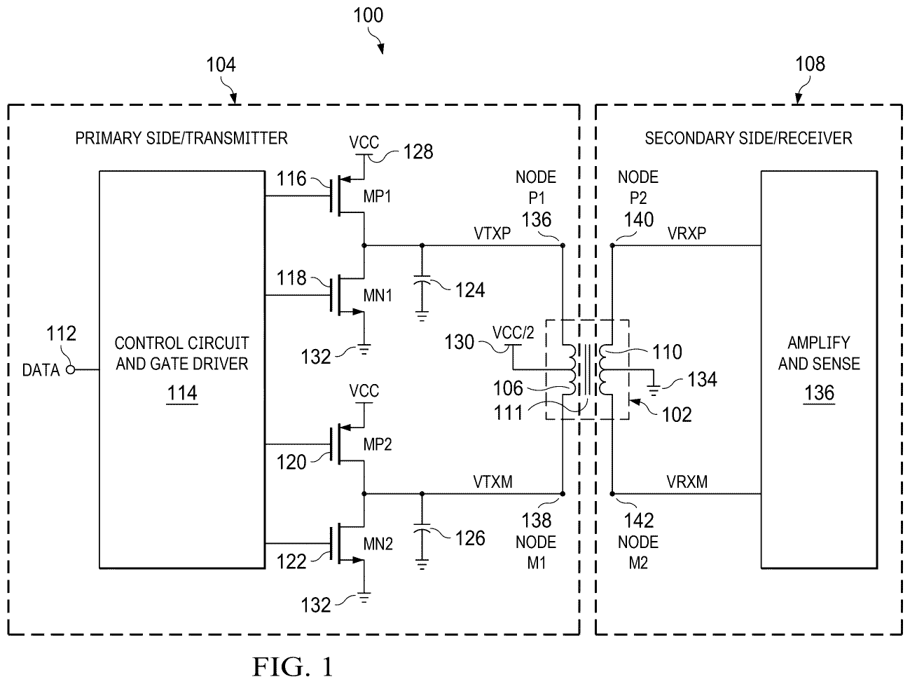

FIG. 1 is a functional block and circuit diagram of an example transceiver system 100 for communicating across a transformer 102. In some examples, the transceiver system 100 enables edged based data transmission, in which transmission occurs responsive to both rising and falling edges of a clock signal provided by a clock circuit (not shown). Accordingly, transmission of a digital bit of data is enabled twice per period of the clock signal. In some examples, using edge based data transmission saves power. In an example, a clock signal frequency is 75 megahertz, and a maximum data rate is 150 megabits per second.

The transceiver system 100 includes a primary side 104 with a primary winding 106 of the transformer 102, a secondary side 108 with a secondary winding 110 of the transformer 102, and an isolation barrier 111. The primary winding 106 and the secondary winding 110 are magnetically coupled to each other. The primary side 104 is the transmitter (TX) of the transceiver system 100, and the secondary side 108 is the receiver (RX) of the transceiver system 100.

The primary side 104 includes an input terminal 112 that receives data signals (DATA), a control circuit and gate driver block 114, a first p-channel MOSFET (MP1) 116, a first n-channel MOSFET (MN1) 118, a second p-channel MOSFET (MP2) 120, a second n-channel MOSFET (MN2) 122, a first capacitor 124, a second capacitor 126, a first primary voltage source (VCC) terminal 128 providing a voltage VCC (from a first voltage source not shown), a second primary voltage source (VCC/2) terminal 130 providing a voltage VCC/2 (from a second voltage source not shown), and a primary side ground terminal 132 (at which a first ground voltage is provided). The secondary side 106 includes a secondary side ground terminal 134 (at which a second ground voltage is provided), and an amplify and sense circuit 136. In an example, the primary side ground terminal 132 is electrically isolated from the secondary side ground terminal 134.

In the examples described herein, the ground terminal is structured to be coupled (e.g., routed) to a portion of a device or device packaging that supplies a common potential, such as electrical ground. In some examples, the primary side ground terminal 132 and/or the secondary side ground terminal 134 is structured to be coupled to a conductive layer, which has a potential considered to be common to circuitry of the device (often referred to as ground), by electrical traces. In such examples, the conductive layer that is set to the ground potential may be referred to as a ground plane. In the described examples, a ground terminal is at least one of a lead, pad, trace, or other component of a circuit (such as an integrated circuit) or package, which may be coupled to a conductive layer set to the common potential.

MP1 116, MN1 118, MP2 120, and MN2 122 are collectively referred to as the primary switches 116, 118, 120, and 122. The primary switches 116, 118, 120, and 122 control the signal provided to the primary winding 106 for transmission to the secondary side 108 in response to the DATA signal.

In some examples, the primary side 104, other than the primary winding 106, is included in an integrated circuit (IC) fabricated on a semiconductor die. In some examples, the IC includes the primary winding 106. In some examples, the secondary side 108, other than the secondary winding 110, is included in an IC. In some examples, the IC includes the secondary winding 110. In some examples, an IC includes the transceiver system 100.

In some examples, the second primary voltage source terminal 130 is connected to the first primary voltage source terminal 128 via a voltage divider, such as a resistor divider or other circuit that derives the voltage at the second primary voltage source terminal 130 from the voltage at the first primary voltage source terminal 128. In some examples, the first capacitor 124 represents parasitic capacitances of MP1 116 and MN1 118, and the second capacitor 126 represents parasitic capacitances of MP2 120 and MN2 122, respectively.

The input terminal 112 is connected to an input of the control circuit and gate driver block 114. A first output of the control circuit gate driver block 114 is connected to a gate of MP2 120, a second output of the control circuit gate driver block 114 is connected to a gate of MN2 122, a third output of the control circuit gate driver block 114 is connected to a gate of MP1 116, and a fourth output of the control circuit gate driver block 114 is connected to a gate of MN1 118. A source of MP1 116 and a source of MP2 120 are connected to the first primary voltage source terminal 128. A source of MN1 118 and a source of MN2 122 are connected to the primary side ground terminal 132.

Drains of MP1 116 and MN1 118 are connected to a first terminal of the first capacitor 124 and a first terminal of the primary winding 106. The drains of MP1 116 and MN1 118 provide a voltage VTXP, a plus polarity transmitter voltage, to the first terminal of the primary winding 106. Drains of MP2 120 and MN2 122 are connected to a first terminal of the second capacitor 126 and a second terminal of the primary winding 106. The drains of MP2 120 and MN2 122 provide a voltage VTXM, a minus polarity transmitter voltage, to the second terminal of the primary winding 106. Second terminals of the first and second capacitors 124 and 126 are connected to the primary side ground terminal 132. The second primary voltage source terminal 130 is connected to a center tap of the primary winding 106. Accordingly, the center tap of the primary winding 106 is biased to VCC/2.

A center tap of the secondary winding 110 is connected to the secondary side ground terminal 134. A first terminal of the secondary winding 110 is connected and provides a voltage VRXP, a plus polarity receiver voltage, to a first input of the amplify and sense circuit 136. A second terminal of the secondary winding 110 is connected and provides a voltage VRXM, a minus polarity receiver voltage, to a second input of the amplify and sense circuit 136. The center taps on the transformer 102 improve resilience of the transformer system 100 against common mode noise by sinking or providing current during common mode noise events.

A node P1 136 is located between the drains of MP1 116 and MN1 118 and the first terminal of the primary winding 106, and a node M1 138 is located between the drains of MP2 120 and MN2 122 and the second terminal of the primary winding 106. A node P2 140 is located between the first terminal of the secondary winding 110 and the first input of the amplify and sense circuit 136, and a node M2 142 is located between the second terminal of the secondary winding 110 and the second input of the amplify and sense circuit 136.

Accordingly, VTXP is the voltage at node P1 136, VTXM is the voltage at node M1 138, VRXP is the voltage at node P2 140, and VRXM is the voltage at node M2 142. A difference between VTXP and VTXM, VTXP-VTXM, corresponds to a voltage across the primary winding 106, which determines a current through and a voltage across the secondary winding 110. The voltage across the secondary winding corresponds to the voltage between node P2 140 and node M2 142, which equals the differential voltage VRXP-VRXM. Accordingly, the differential voltage VTXP-VTXM determines a signal transmitted from the primary winding 106 to the secondary winding 110, which corresponds to a signal transmitted from the transmitter 104 to the receiver 108.

Herein, a voltage VTXP-VTXM oriented from node P1 136 to node M1 138 is described as a positive voltage across the primary winding 106, and a voltage VTXP-VTXM oriented from node M1 138 to node P1 136 is described as a negative voltage across the primary winding 106. Similarly, a voltage VRXP-VRXM oriented from node P2 140 to node M2 141 is described as a positive voltage across the secondary winding 110, and a voltage VRXP-VRXM oriented from node M2 142 to node P2 140 is described as a negative voltage across the secondary winding 110.

In some examples, a higher voltage DATA signal corresponds to a logic one, and a lower voltage DATA signal corresponds to a logic zero. In some examples, a higher voltage DATA signal corresponds to a logic zero, and a lower voltage DATA signal corresponds to a logic one.

The control circuit and gate driver block 114 decodes the DATA signal and drives the gates of MP1 116, MN1 118, MP2 120, and MN2 122 accordingly. In some examples, DATA signal decoding by the control circuit and gate driver block 114 corresponds to edge detection. The control circuit and gate driver block 114 drives MP1 116, MN1 118, MP2 120, and MN2 122 so that only one of MP1 116 and MP2 120 is turned on at a time, only one of MN1 118 and MN2 122 is turned on at a time, only one of MP1 116 and MN1 118 is turned on at a time, and only one of MP2 120 and MN2 122 is turned on at a time.

In response to the DATA signal having a first direction edge (such as a rising edge corresponding to a logic one), the control circuit and gate driver block 114 drives MP1 116 to turn on to provide VCC to node P1 136 so that VTXP equals VCC, and drives MN2 122 to turn on to provide a ground voltage (such as a zero voltage) to node M1 138 so that VTXM equals zero. The control circuit and gate driver block 114 also drives MN1 118 and MP2 120 to turn off. Accordingly, the voltage across the primary winding 106 VTXP-VTXM in response to a logic one DATA signal value equals VCC.

In response to the DATA signal having a second direction edge (such as a falling edge corresponding to a logic zero), the control circuit and gate driver block 114 drives MP2 120 to turn on to provide VCC to node M1 138 so that VTXM equals VCC, and drives MN1 118 to turn on to provide the ground voltage to node P1 136 so that VTXP equals zero. The control circuit and gate driver block 114 also drives MP1 116 and MN2 122 to turn off. Accordingly, the voltage across the primary winding 106 VTXP-VTXM in response to a logic zero DATA signal value equals-VCC (negative VCC).

As described above, the center tap of the primary winding 106 is biased to VCC/2, so that VTXP and VTXM are pulled to VCC/2 while MP1 116, MN1 118, MP2 120, and MN2 122 are turned off, such as between transmission of a DATA value from the transmitter 104 to the receiver 108. Accordingly, when the control circuit and gate drive block 114 controls MP1 116, MN1 118, MP2 120, and MN2 122 responsive to a DATA signal value to determine the two TX single ended outputs VTXP and VTXM, one of VTXP and VTXM swings from VCC/2 to VCC, and the other of VTXP and VTXM swings from VCC/2 to zero volts. As described above, the voltage values to which VTXP and VTXM swing depend on the DATA signal. Accordingly, VTXP and VTXM swing symmetrically so that, for example, if VTXP goes up by 0.8 volts, then VTXM goes down by 0.8 volts, and if VTXP goes down by 0.8 volts, then VTXM goes up by 0.8 volts. VRXP and VRXM similarly symmetrically swing around the voltage of the center tap of the secondary winding 110, such as zero volts.

The differential swing of VTXP and VTXM may reach the receiver 108 with some attenuation. As described above, the receiver 108 receives two single ended voltages, VRXP and VRXM, which together correspond to the differential voltage VRXP-VRXM across the secondary winding 110. VRXP and VRXM are decoded by the receiver 108 using the amplify and sense circuit 136.

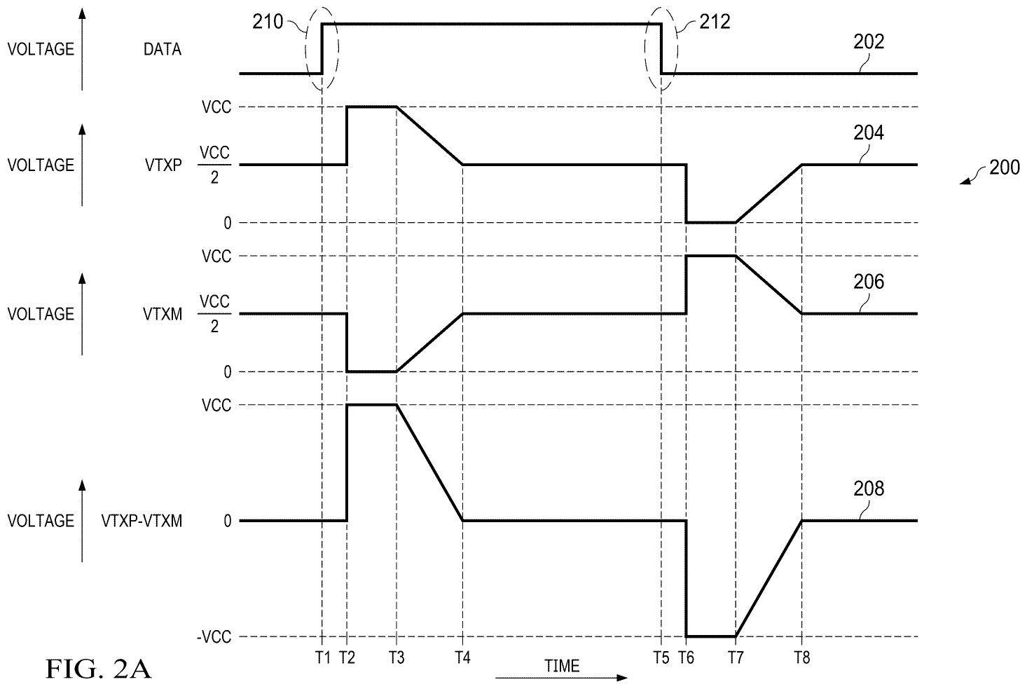

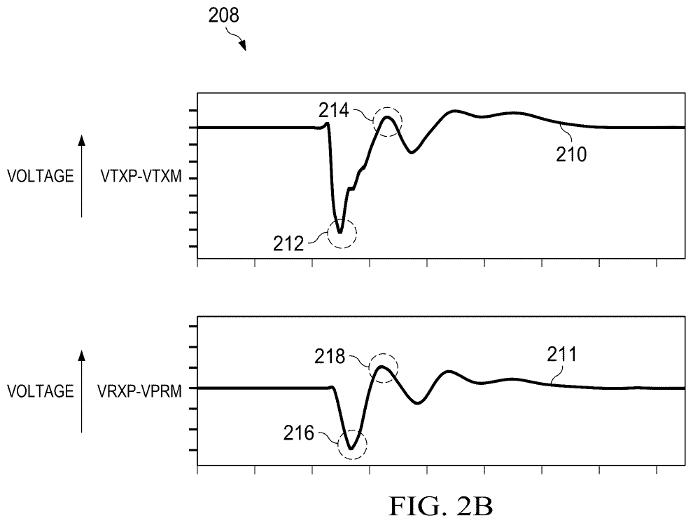

The parasitic capacitances (the first and second capacitors) 124 and 126, along with the transformer 102, form a resonant network. This introduces ringing (a nonlinear oscillation) into the differential output of the transmitter 104, accordingly, into the energy that the transmitter 104 provides and stores in the magnetic core of the transformer 102 to be transferred to the receiver 108. This ringing, which can cause false signal detection in the receiver 108 if not suppressed (reduced or eliminated), is further described with respect to FIGS. 2A and 2B.

FIG. 2A is a set of graphs 200 of example ideal signals of the transceiver system 100 of FIG. 1. Vertical axes correspond to voltage, and a horizontal axis corresponds to time. A first signal corresponds to a DATA signal 202, which is received by the control circuit and gate driver block 114. A second signal corresponds to VRXP 204, a third signal corresponds to VRXM 206, and a fourth signal corresponds to VTXP minus VTXM (VTXP-VTXM) 206.

In the example illustrated in FIG. 2A, the DATA signal 202 swings between a low voltage and a high voltage. The control circuit and gate driver block 114 detects a rising edge 210 of the DATA signal 202 as corresponding to a first logic value, such as a logic one. The control circuit and gate driver block 114 detects a falling edge 212 of the DATA signal 202 as corresponding to a second logic value, such as a logic zero. As described above, VTXP 204 and VTXM 206 equal VCC/2 while the transmitter 104 is not transmitting.

At time T1, the control circuit and gate driver block 114 detects a rising edge 210 in the DATA signal 202 corresponding to a logic one. After a signal propagation time, at time T2, the control circuit and gate driver block 114 causes MP1 116 to turn on, MN1 118 to turn off, MP2 120 to turn off, and MN2 122 to turn on. This causes VTXP 204 to equal VCC and causes VTXM 206 to equal zero. Accordingly, VTXP-VTXM 208, corresponding to the voltage across the primary winding 106, equals VCC to transmit the logic one from the transmitter 104 to the receiver 108 via the transformer 102. At time T3 the control circuit and gate driver block 114 drives MP1 116 and MN2 122 to turn off, so that from time T3 to time T4 VTXP 204, VTXM 206, and VTXP-VTXM 208 return to their default values.

At time T5, the control circuit and gate driver block 114 detects a falling edge 212 in the DATA signal 202 corresponding to a logic zero. After a signal propagation time, at time T6, the control circuit and gate driver block 114 causes MP1 116 to turn off, MN1 118 to turn on, MP2 120 to turn on, and MN2 122 to turn off. This causes VTXP 204 to equal zero and causes VTXM 206 to equal VCC. Accordingly, VTXP-VTXM 208 equals-VCC to transmit the logic zero from the transmitter 104 to the receiver 108 via the transformer 102. At time T7 the control circuit and gate driver block 114 drives MP2 118 and MN1 120 to turn off, so that from time T7 to time T8 VTXP 204, VTXM 206, and VTXP-VTXM 208 return to their default values. In an example, a pulse length of VTXP-VTXM 208, corresponding to T2 to T3 or from T6 to T7, is less than one nanosecond.

FIG. 2B is a set of graphs 208 of voltage against time for a transmitted signal 210 and a received signal 211 according to the transceiver system 100 of FIG. 1. Vertical axes correspond to voltage, and a horizontal axis corresponds to time. The transmitted signal 210 is a measured or simulated version of the ideal VTXP minus VTXM signal 206 described with respect to FIG. 2A, and the received signal 211 is a measured or simulated VRXP minus VRXM signal 211. As described with respect to FIG. 1, VRXP is received by a first terminal of the secondary winding 110, and VRXM is received by a second terminal of the secondary winding 110.

The transmitted signal 210 corresponds to a logic zero DATA signal 202. Accordingly, the voltage of the transmitted signal 210 goes from a default voltage (flat horizontal portion of transmitted signal 210) to-VCC, then returns to the default voltage. In some examples, the default voltage is zero volts. The transmitted signal 210 has a primary peak 212 (low voltage peak, or trough) and, because of ringing related to the resonant circuit that includes the transformer 102 and the first and second capacitors 124 and 126 (parasitic capacitances), also has a secondary peak 214.

Similarly, the voltage of the received signal 211 goes from a default voltage such as zero volts, to a primary peak 216, to a secondary peak 218. The primary peak 216 corresponds to a valid detected logic zero. In some examples, the secondary peak 218 may rise sufficiently above zero volts to potentially cause false detection of a logic one.

The illustrated primary peak 216 has a negative voltage corresponding to a logic zero. In some examples, a primary peak 216 may have a positive voltage corresponding to a logic one. The illustrated secondary peak 218 has a positive voltage responsive to the negative voltage primary peak 216. In some examples, a secondary peak 218 may have a negative voltage responsive to a primary voltage primary peak 216.

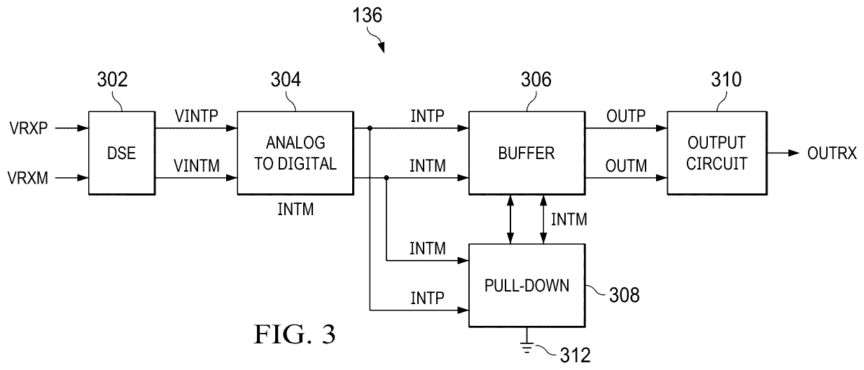

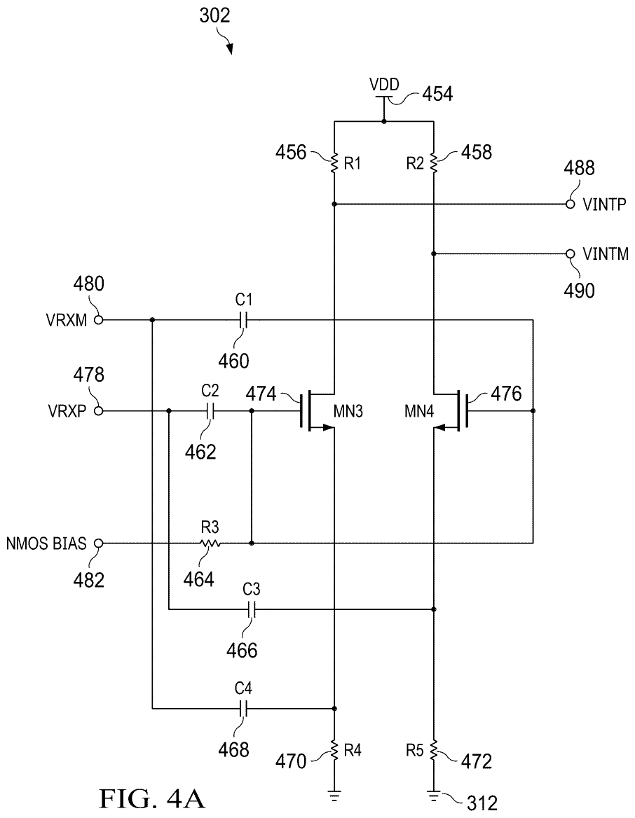

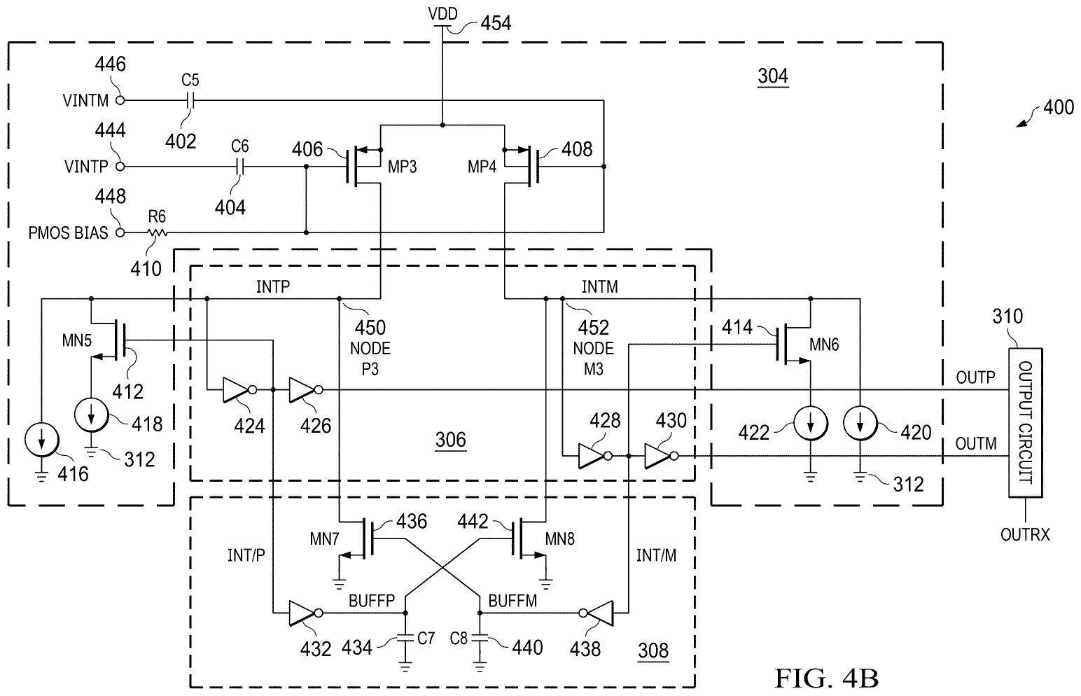

FIG. 3 corresponds to a first example, and FIGS. 4A and 4B together correspond to a second example, of the amplify and sense circuit 136 of FIG. 1. The circuits of FIG. 3, and/or of FIGS. 4A and 4B, enable detection of the primary peak 216, and enable subsequent peaks responsive to the primary peak 216 to be suppressed.

FIG. 3 is a functional block diagram of an example of the amplify and sense circuit 136 of FIG. 1. The amplify and sense circuit 136 includes a differential to single ended (DSE) circuit 302, an analog to digital circuit 304, a buffer circuit 306, a pull-down circuit 308, an output circuit 310, and a secondary ground terminal 312. In some examples, the analog to digital circuit 304 also acts as an amplifier.

The DSE circuit 302 receives the VRXP signal from the secondary winding 302 at a first input, and receives the VRXM signal from the secondary winding 302 at a second input. A first output of the DSE circuit 302 is connected and provides a VINTP signal (analog plus polarity intermediate output voltage) to a first input of the analog to digital circuit 304. A second output of the DSE circuit 302 is connected and provides a VINTM signal (analog minus polarity intermediate output voltage) to a second input of the analog to digital circuit 304.

A first output of the analog to digital circuit 304 is connected and provides an INTP signal (digital plus polarity intermediate output) to first inputs of the buffer circuit 306 and the pull-down circuit 308. A second output of the analog to digital circuit 304 is connected and provides an INTM signal (digital minus polarity intermediate output) to first inputs of the buffer circuit 306 and the pull-down circuit 308. The pull-down circuit 308 is connected to the secondary ground terminal 312. The buffer circuit 306 and the pull-down circuit 308 are connected so that the pull-down circuit 308 can selectively connect the INTP signal or the INTM signal to the secondary ground terminal 312. A first output of the buffer circuit 306 is connected and provides an OUTP signal (plus polarity output) to the output circuit 310. A second output of the buffer circuit 306 provides an OUTM signal (minus polarity output) to the output circuit. The output circuit 310 provides the digital output data signal OUTRX of the receiver 108.

The DSE circuit 302 provides to the buffer circuit 306 and the pull-down circuit 308 a single ended signal VINTP or VINTM in response to the differential signals VRXP and VRXM received from the secondary winding 108. The single ended signal indicates a primary peak 216 corresponding to either a logic one or a logic zero using a corresponding one of VINTP or VINTM. However, as described above, a secondary peak 218 may be received that is strong enough to cause a logic zero or logic one to be falsely detected and passed on via VINTP or VINTM, accordingly, via the signal not used to indicate the primary peak 216.

The analog to digital circuit 304 converts the analog single ended signal corresponding to the primary peak 216 to a digital signal INTP or INTM, corresponding to VINTP or VINTM, respectively. As described above, the primary peak 216 arrives at the receiver 108 before the secondary peak 218. Accordingly, the digital signal corresponding to the primary peak 216 (INTP or INTM) activates the pull-down circuit 308 to connect the other signal (INTM or INTP, respectively) to the secondary ground terminal 312, which suppresses any signal corresponding to a secondary peak 218. The pull-down circuit 308 maintains the activated state long enough to prevent spurious detection of a data bit due to signal effects downstream of ringing in VRXP and VRXM responsive to the primary peak 216.

FIG. 4A is a circuit diagram of an example of the DSE circuit 302 of FIG. 3. The DSE circuit 302 includes a secondary voltage source (VDD) 454 providing a voltage VDD, a first resistor (R1) 456 with resistance R1, a second resistor (R2) 458 with resistance R2, a first capacitor (C1) 460, a second capacitor (C2) 462, a third resistor (R3) 464, a third capacitor (C3) 466, a fourth capacitor (C4) 468, a fourth resistor (R4) 470, a fifth resistor (R5) 472, a third n-type MOSFET (MN3) 474, and a fourth n-type MOSFET (MN4) 476. In FIGS. 4A, 4B, and 4C, multiple instances of the secondary ground terminal 312 are shown, but to reduce clutter, only some instances of the secondary ground terminal 312 are labeled.

A first terminal 478 is connected to the first terminal of the secondary winding 110 to receive VRXP, and a second terminal 480 is connected to the second terminal of the secondary winding 110 to receive VRXM. The first terminal 478 is connected and provides VRXP to a first terminal of C2 462 and a first terminal of C3 466. The second terminal 480 is connected and provides VRXM to a first terminal of C1 460 and a first terminal of C4 468. A second terminal of C2 462 is connected to the gate of MN3 474, the gate of MN4 476, a second terminal of R3 464, and a second terminal of C1 460. The first and second terminals 478 and 480 correspond to data input terminals of the circuit 302, and in some examples, of the amplify and sense circuit 136

A third terminal 482 receives an NMOS bias voltage and is connected to a first terminal of R3 464. The NMOS bias voltage is selected to enable a high transconductance of MN3 474 and MN4 476, and to enable MN3 478 and/or MN4 480 to rapidly change conductivity. Accordingly, the NMOS bias voltage affects the gain and response times of the output signals VINTP and VINTM of the DSE circuit 302, increasing receiver 108 sensitivity and maximum data rate.

A second terminal of C3 466 is connected to a source of MN4 476 and a first terminal of R5 472. A second terminal of C4 468 is connected to a source of MN3 474 and a first terminal of R4 470. Second terminals of R4 470 and R5 472 are connected to the secondary ground terminal 312.

A drain of MN3 474 is connected to a first terminal of R1 456 and a fourth terminal 488. The fourth terminal 488 has an analog plus polarity intermediate output voltage VINTP. A drain of MN4 480 is connected to a first terminal of R2 458 and a fifth terminal 490. The fifth terminal 490 has an analog minus polarity intermediate output voltage VINTM. Second terminals of R1 456 and R2 458 are connected to the secondary voltage source 454. The fourth and fifth terminals 488 and 490 correspond to output terminals of the DSE circuit 302. Accordingly, VINTP and VINTM are output voltages of the DSE circuit 302. The output voltages of the DSE circuit 302 of FIG. 4A are input voltages of the circuit 400 of FIG. 4B.

In some examples, MN3 474 and MN4 476 remain turned on while the transceiver system 100 is turned on. Changes in VRXP and VRXM responsive to signals received by the receiver 108 change make one of MN3 474 and MN4 476 more conductive, and make the other of MN3 474 and MN4 476 less conductive. VINTP has a default voltage corresponding to VDD minus resistance R1 multiplied by a current through R1 456 while VRXP equals zero. VINTM has a default voltage corresponding to VDD minus resistance R2 multiplied by a current through R2 458 while VRXM equals zero.

When a logic one is sent from the transmitter 104 to the receiver 108, accordingly from the primary side 104 to the secondary side 108, VRXP goes high and VRXM goes low, corresponding to a positive voltage primary peak 216 in the VRXP minus VRXM signal 211. This causes MN3 474 to become more conductive and causes MN4 476 to become less conductive. When M3 474 becomes more conductive, current through M3 474 increases, so that the voltage drop across R1 456 increases and VINTP decreases. When M4 476 becomes less conductive, current through M4 476 decreases, so that the voltage drop across R2 458 decreases and VINTM increases. This false detection can be suppressed later in the signal path, as further described with respect to FIGS. 3, 4A, 4B, 5, and 7.

Similarly, when a logic zero is sent from the transmitter 104 to the receiver 108, VRXP goes low and VRXM goes high, corresponding to a negative voltage primary peak 216 in the VRXP minus VRXM signal 211. This causes MN3 474 to become less conductive and causes MN4 476 to become more conductive. While M3 474 is less conductive, current through M3 474 decreases, so that the voltage drop across R1 456 decreases and VINTP increases. While M4 476 is more conductive, current through M4 476 increases, so that the voltage drop across R2 458 increases and VINTM decreases. A reduction in VINTP or VINTM corresponding to a received primary peak 216 corresponding to a transmitted data signal is referred to herein as a reduced voltage pulse.

In some examples, fluctuation of VRXM in response to a negative voltage secondary peak 218 in the VRXP minus VRXM signal 211 may cause MN4 476 to become sufficiently conductive to cause voltage VINTM to mimic a reduced voltage pulse. This spurious reduced voltage pulse may lead to false detection of a logic zero following the intended logic one. In some examples, fluctuation of VRXP in response to a positive voltage secondary peak 218 in the VRXP minus VRXM signal 211 may cause MN3 474 to become sufficiently conductive to cause voltage VINTP to mimic a reduced voltage pulse. This spurious reduced voltage pulse may lead to false detection of a logic one following the intended logic zero. False detection of received data values responsive to secondary peaks 218 can be suppressed, as further described with respect to FIGS. 3, 4A, 4B, 5, and 7.

FIG. 4B is a circuit diagram of an example circuit 400 that includes the analog to digital circuit 304, buffer circuit 306, pull-down circuit 308, and output circuit 310 of FIG. 3. The analog to digital circuit 304 converts VINTP and VINTM into digital signals INTP and INTM. The buffer circuit 306 and the pull-down circuit 308 determine a plus polarity output signal OUTP and a minus polarity output signal OUTM responsive to the digital signals INTP and INTM.

The analog to digital circuit 304 includes a fifth capacitor (C5) 402, a sixth capacitor (C6) 404, a third p-channel MOSFET (MP3) 406, a fourth p-channel MOSFET (MP4) 408, a sixth resistor (R6) 410, a fifth n-channel MOSFET (MN5) 412, a sixth n-channel MOSFET (MN6) 414, a first current source 416, a second current source 418, a third current source 420, and a fourth current source 422.

The buffer circuit 306 includes a first inverter 424, a second inverter 426, a third inverter 428, and a fourth inverter 430.

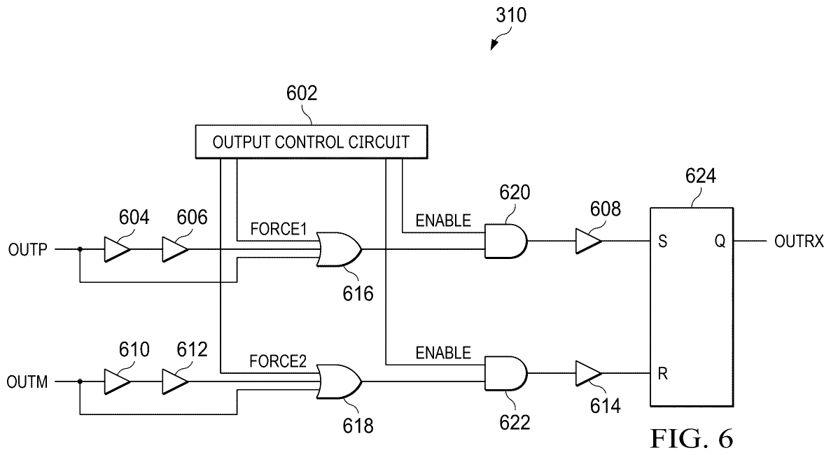

The pull-down circuit 308 includes a fifth inverter 432, a seventh capacitor (C7) 434, a seventh n-channel MOSFET (MN7) 436, a sixth inverter 438, an eighth capacitor (C8) 440, and an eighth n-channel MOSFET (MN8) 442. The output circuit 310 is further described with respect to FIG. 6.

A fourth terminal 444 is connected and provides VINTP to a first terminal of C6 404. A fifth terminal 446 is connected and provides VINTM to a first terminal of C5 402. A second terminal of C6 404 is connected to a second terminal of R6 410, a gate of MP3 406, a gate of MP4 408, and a second terminal of C5 402. A sixth terminal 448 receives a PMOS bias voltage and is connected to a first terminal of R6 410. Sources and back-gates of MP3 406 and MP4 408 are connected to the secondary voltage source 454. A back-gate of a transistor is also referred to as the body terminal or bulk terminal of the transistor. A drain of MP3 406 is connected and provides a digital plus polarity intermediate output signal INTP to a node P3 450. A drain of MP4 408 is connected and provides a digital minus polarity intermediate output signal INTM to a node M3 452.

Node P3 450 is connected to a first terminal of the first current source 416, a drain of MN5 412, an input of the first inverter 424, and a drain of MN7 436. A source of MN5 412 is connected to a first terminal of the second current source 418. Second terminals of the first and second current sources 416 and 418 are connected to the secondary ground terminal 312. A gate of MN5 412 is connected to an output of the first inverter 424, an input of the second inverter 426, and an input of the fifth inverter 432. An output of the second inverter 426 is connected and provides OUTP to a first input of the output circuit 310.

Node M3 452 is connected to a first terminal of the third current source 420, a drain of MN6 414, an input of the third inverter 428, and a drain of MN8 442. A source of MN6 414 is connected to a first terminal of the fourth current source 422. Second terminals of the third and fourth current sources 420 and 422 are connected to the secondary ground terminal 312. A gate of MN6 414 is connected to an output of the third inverter 428, an input of the fourth inverter 430, and an input of the sixth inverter 438. An output of the fourth inverter 430 is connected and provides OUTM to a second input of the output circuit 310. The output circuit 310 provides the digital output data signal for the receiver 108, OUTRX.

In the pull-down circuit 308, an output of the fifth inverter 432 is connected to a first terminal of C7 434 and a gate of MN8 442. An output of the sixth inverter 438 is connected to a first terminal of C8 440 and a gate of MN7 436. Second terminals of C7 434 and C8 440 and sources of MN7 436 and MN8 442 are connected to the secondary ground terminal 312. MP3 406 is designed so that, in response to the PMOS bias voltage and the default value of VINTP (see description of FIG. 4A), MP3 406 provides a current I to node P3 450. Similarly, MP4 408 is designed so that, in response to the PMOS bias voltage and the default value of VINTM, MP4 408 provides a current I to node M3 452. The first and second current sources 416 and 418 together sink a current 3×I from node P3 450. Also, the third and fourth current sources 420 and 422 together sink a current 3×I from node M3 452. Note that MP3 406 and MP4 408 become less conductive and carry less current if VINTP or VINTM, respectively, increases. Accordingly, node P3 450 is discharged to zero volts by the first and second current sources 416 and 418 responsive to VINTP having a voltage corresponding to no received signal or a received signal corresponding to a logic zero. Node M3 452 is discharged to zero volts by the third and fourth current sources 420 and 422 responsive to VINTM having a voltage corresponding to no received signal or a received signal corresponding to a logic one.

When VINTP corresponds to a reduced voltage pulse, MP3 406 becomes more conductive, so that a current through MP3 406 increases. If VINTP decreases sufficiently, such as in response to a positive primary peak 216, a current through MP3 406 exceeds 3×I, so that more current is sourced to node P3 450 than is sunk from node P3 450. This causes INTP to go high. The first and second inverters 424 and 426 generate the signal OUTP with shorter rise and fall times than the square wave INTP, so that OUTP more closely conforms to a pulse with steep rise and fall curves and a relatively short interval from rise to fall. In an example, a pulse width of OUTP can be 6.66 ns, corresponding to 150 megabits per second.

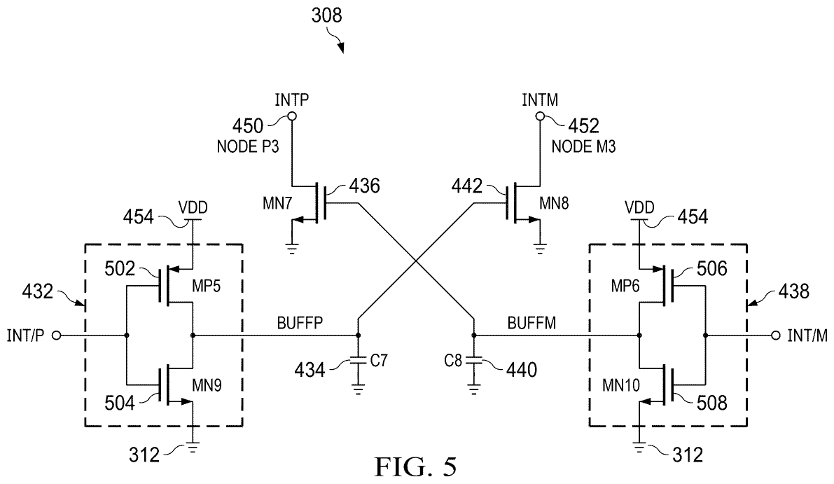

The output of the first inverter 424 is INT/P, accordingly, inverted INTP. The fifth inverter 432 provides an output signal BUFFP (buffered inverted INT/P) with a fall curve (voltage curve falling from high to low) that is shallower than a corresponding rise curve of INT/P. In some examples, as described with respect to FIG. 5, certain transistors (such as NMOS) in the fifth inverter 432 have a length parameter selected to make shallower (lengthen) the fall curve of BUFFP. A capacitance of C7 434 is selected to further lengthen a voltage fall time for BUFFP. Accordingly, when INTP goes high BUFFP goes high, corresponding to a positive primary peak 216 indicating a logic one signal. Responsive to BUFFP going high MN8 442 turns on, tying node M3 452 to the secondary ground terminal 312, which pulls INTM down to the ground voltage. Because the fall time for BUFFP is lengthened by the fifth inverter 432 and C7 434, node M3 452 remains tied to the secondary ground terminal 312 past the secondary peak 218 (if any).

In some examples, properties of the fourth inverter 428 and of C7 430 are selected so that MN8 446 is kept turned on past a time when ringing could cause false detection of a transmitted data signal value. In some examples, properties of the fourth inverter 428 and C7 430 are selected so that MN8 446 reliably turns off prior to a sequentially subsequent data pulse received by the receiver 108.

Similarly, when VINTM corresponds to a reduced voltage pulse, MP4 408 becomes more conductive, so that a current through MP4 408 increases. If VINTM decreases sufficiently, such as in response to a negative primary peak 216, a current through MP4 408 exceeds 3×I, so that more current is sourced to node M3 452 than is sunk from node M3 452. This causes INTM to go high. The third and fourth inverters 428 and 430 generate the signal OUTM with shorter rise and fall times than the square wave INTM, so that OUTM more closely conforms to a pulse with steep rise and fall curves and a relatively short interval from rise to fall.

The output of the third inverter 428 is INT/M, accordingly, inverted INTM. The sixth inverter 438 provides an output signal BUFFM (buffered inverted INT/M) with a fall curve (voltage curve falling from high to low) that is shallower than a corresponding rise curve of INT/M. In some examples, as described with respect to FIG. 5, certain transistors (such as NMOS) in the sixth inverter 438 have a length parameter selected to make shallower (lengthen) the fall curve of BUFFP. A capacitance of C8 440 is selected to further lengthen a voltage fall time for BUFFM. Accordingly, when INTM goes high BUFFM goes high, corresponding to a negative primary peak 216 indicating a logic zero signal. Responsive to BUFFM going high MN7 436 turns on, tying node P3 450 to the secondary ground terminal 312, which pulls INTP down to the ground voltage. Because the fall time for BUFFM is lengthened by the sixth inverter 438 and C8 440, node P3 450 remains tied to the secondary ground terminal 312 past the secondary peak 218 (if any).

Accordingly, MN7 436 turning on corresponds to activating the pull-down circuit 308 to connect INTP to the secondary ground terminal 312 and suppress false detection of received logic one DATA signals, as described with respect to FIG. 3. Similarly, MN8 442 turning on corresponds to activating the pull-down circuit 308 to connect INTM to the secondary ground terminal 312 and suppress false detection of received logic zero DATA signals.

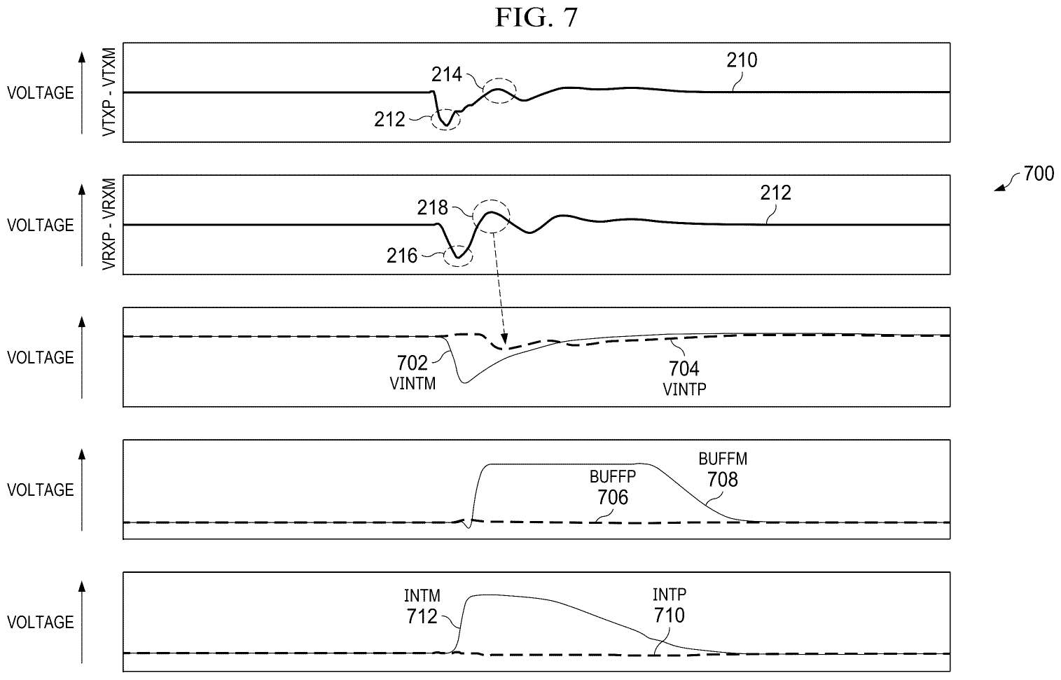

In some examples, properties of the fifth inverter 432 and of C7 434 are selected so that MN8 442 is kept turned on past a time when ringing could cause false detection of a transmitted data signal value. In some examples, properties of the fifth inverter 432 and C7 434 are selected so that MN8 442 reliably turns off prior to a sequentially subsequent data pulse received by the receiver 108. The fifth and sixth inverters 432 and 438, and C7 434 and C8 440, are further described with respect to FIG. 5. The output circuit 310 is further described with respect to FIG. 6. An example BUFFM signal that goes high to turn on MN7 436 and pull down INTP is described with respect to FIG. 7.

FIG. 5 is a circuit diagram of an example of the pull-down circuit 308 of FIGS. 3 and 4. The pull-down circuit includes a fifth p-channel MOSFET (MP5) 502, a ninth n-channel MOSFET (MN9) 504, a sixth p-channel MOSFET (MP6) 506, and a tenth n-channel MOSFET (MN10) 508. Gates of MP5 502 and MN9 504 receive INT/P, and gates of MP6 506 and MN10 508 receive INT/M. Sources of MP5 502 and MP6 506 are connected to the secondary voltage source 454, and sources of MN9 504 and MN10 508 are connected to the secondary ground terminal 312. The drains of MP5 502 and MN9 504 are connected to the first terminal of C7 434 and the gate of MN8 442. The drains of MP6 506 and MN10 508 are connected to the first terminal of C8 440 and the gate of MN7 436.

In some examples, the width and length of MN9 504 are selected to enable a slower discharge of the BUFFP signal after INT/P goes high, accordingly, after the VRXP primary peak 216 and corresponding high INTP signal end. This slower discharge of BUFFP causes MN8 442 to stay on longer. In some examples, the width and length of MN9 504, and a capacitance of C7 434, are selected so that BUFFP stays high to keep MN8 442 turned on long enough to reliably avoid false detection of a data signal responsive to INTM.

Similarly, the width and length of MN10 508 are selected to enable a slower discharge of the BUFFM signal after INT/M goes high, accordingly, after the VRXM primary peak 216 and corresponding high INTM signal end. This slower discharge of BUFFM causes MN7 436 to stay on longer. In some examples, the width and length of MN10 508, and a capacitance of C8 440, are selected so that BUFFM stays high to keep MN7 436 turned on long enough to reliably avoid false detection of a data signal responsive to INTP. In some examples, a 150 megabits per second data rate is used with sub-nanosecond DATA signal pulses (each pulse corresponding to one binary bit) with 7 nanoseconds between DATA signal pulses. In some examples according to these characteristics, following detection of a primary peak 216 (INTP or INTM goes high), MN7 436 or MN8 442 is kept turned on for one nanosecond to suppress false data detection responsive to signal ringing.

In some examples, C7 434 and/or C8 440 are constructed to include one or more transistors connected in parallel. In some examples, MN9 504 and/or MN10 508 are constructed to include multiple transistors connected in parallel to vary a signal slope during transistor turn off.

FIG. 6 is a functional block diagram of the output circuit 310 of FIGS. 3 and 4. The output circuit 310 includes an output control circuit 602, a first buffer 604, a second buffer 606, a third buffer 608, a fourth buffer 610, a fifth buffer 612, a sixth buffer 614, a first logical OR gate 616, a second logical OR gate 618, a first logical AND gate 620, a second logical AND gate 622, and an S-R latch 624. In an example, the output control circuit 602 is implemented using digital logic.

A seventh terminal 626 receives OUTP from the circuit 400 of FIG. 4B. An input of the first buffer 604 and a first input of the first OR gate 616 are connected to the seventh terminal 626. An output of the first buffer 604 is connected to an input of the second buffer 606. An output of the second buffer 606 is connected to a second input of the first OR gate 616. A first output of the output control circuit 602 is connected, and provides a first FORCE signal to, a third input of the first OR gate 616. An output of the first OR gate 616 is connected to a first input of the first AND gate 620. A second output of the output control circuit 602 is connected, and provides an ENABLE signal to, a second input of the first AND gate 620. An output of the first AND gate 620 is connected to an input of the third buffer 608. An output of the third buffer 608 is connected to an S (set) input of the S-R latch 624.

An eighth terminal 628 receives OUTM from the circuit 400 of FIG. 4B. An input of the fourth buffer 610 and a first input of the second OR gate 618 are connected to the eighth terminal 628. An output of the fourth buffer 610 is connected to an input of the fifth buffer 612. An output of the fifth buffer 612 is connected to a second input of the second OR gate 618. A third output of the output control circuit 602 is connected, and provides a second FORCE signal (FORCE2) to, a third input of the second OR gate 618. An output of the second OR gate 618 is connected to a first input of the second AND gate 622. A second output of the output control circuit 602 is connected, and provides an ENABLE signal to, a second input of the second AND gate 622. An output of the second AND gate 622 is connected to an input of the sixth buffer 614. An output of the sixth buffer 614 is connected to an R (reset) input of the S-R latch 624.

The ENABLE signal is used to turn the output OUTRX from the output circuit 310 on and off. If the ENABLE signal is asserted (logic high), the output circuit 310 provides OUTRX responsive to OUTP and OUTM. If the ENABLE signal is deasserted (logic low), the output circuit 310 provides OUTRX as a zero voltage signal or a NULL signal.

In some examples, the FORCE1 and FORCE2 signals are used to clear invalid voltage signals from the S-R latch 624 or from other components of the output circuit 310 after a device power on (transceiver system 100 power on), or to test output of the output circuit 310. If the FORCE1 signal is asserted (logic one) and the ENABLE signal is asserted then the set input of the S-R latch 624 receives a logic one and the S-R latch 624 is set, accordingly, stores a logic one. If the FORCE2 signal is asserted (logic one) and the ENABLE signal is asserted then the reset input of the S-R latch 624 receives a logic one and the S-R latch 624 is reset, accordingly, stores a logic zero.

The first and second buffers 604 and 606, and the fourth and fifth buffers 610 and 612, are used to lengthen a valid signal duration of OUTP and OUTM, respectively. Accordingly, a signal duration of OUTP or OUTM as received by the S-R latch 624 will equal the signal duration as received by the output circuit 310, plus a delay time added by the first and second buffers 604 and 606 or the fourth and fifth buffers 610 and 612, respectively.

FIG. 7 is a set of graphs 700 of voltage against time for various signals of the receiver 108 of FIGS. 1 and 3-6. Vertical axes correspond to voltage, and a horizontal axis corresponds to time. The graphs 700 show signals including VINTP 702, VINTM 704, BUFFP 706, BUFFM 708, INTP 710, and INTM 712 (FIGS. 4A and 4B). VINTP 702 is at the fourth terminal 444, VINTM 704 is at the fifth terminal 446, BUFFP 706 is at the first terminal of C7 434, BUFFM 708 is at the first terminal of C8 440, INTP is at node P3 450, and INTM is at node M3 452.

As described above, the primary peak 216 and secondary peak 218 in the VRXP minus VRXM signal 211 are respectively responsive to the primary peak 212 and secondary peak 214 in the VTXP minus VTXM signal 210. The dotted line points from the secondary peak 218 to a secondary peak in the VINTP signal 704 that could cause false detection of a data bit. The BUFFM signal 708 is, accordingly, kept high by (for example) the sixth inverter 438 and C8 440 long enough to prevent detection of secondary (or tertiary, or quaternary, etc.) peaks 218. In some examples, this is similar to or longer than a duration that the INTM signal 712 is high. Responsive to the BUFFM 708 signal being high, the INTP 710 signal remains at zero voltage and false data detection is prevented.

In some examples, a transmission type other than edge based transmission is used.

In some examples, a logic one corresponds to a lower voltage DATA signal and a logic zero corresponds to a higher voltage DATA signal.

In some examples, the first inverter 424, the fifth inverter 432, and C7 434 can be described as a buffer that lengthens a duration of a high level of INTP so that MN8 442 is kept turned on to suppress secondary peaks 218 in response to a primary peak 216 corresponding to a logic one DATA signal. In some examples, the third inverter 428, the sixth inverter 438, and C8 440 can be described as a buffer that lengthens a duration of a high level of INTM so that MN7 436 is kept turned on to suppress secondary peaks 218 in response to a primary peak 216 corresponding to a logic zero DATA signal.

In some examples, an RC circuit is used to connect an INTP or INTM signal to a BUFFP or BUFFM signal, respectively. Accordingly, the RC circuit is used to reshape the respective signal to keep MN7 436 or MN8 442 (or other switch) turned on longer to extend a duration during which a secondary peak 218 (or tertiary or quaternary peak, etc.) is suppressed.

In some examples, the pull-down circuit 308 pulls a signal corresponding to secondary peaks 218 down to a voltage that is approximately zero, such as a voltage that is close enough to zero or another low reference voltage to reliably prevent false data detection across process, voltage, and temperature variations.

In some examples, the output control circuit 602 is implemented using a processor such as a microcontroller unit (MCU), digital signal processor (DSP), or central processing unit (CPU).

The term “couple” is used throughout the specification. The term may cover connections, communications, or signal paths that enable a functional relationship consistent with this description. For example, if device A provides a signal to control device B to perform an action, in a first example device A is coupled to device B, or in a second example device A is coupled to device B through intervening component C if intervening component C does not substantially alter the functional relationship between device A and device B such that device B is controlled by device A via the control signal provided by device A.

Although the term “connected” is used herein, one or more of the described connections can be direct without intervening components or indirect with one or more intervening components.

In this description, the term “and/or” (when used in a form such as A, B and/or C) refers to any combination or subset of A, B, C, such as: (a) A alone; (b) B alone; (c) C alone; (d) A with B; (c) A with C; (f) B with C; and (g) A with B and with C. Also, as used herein, the phrase “at least one of A or B” (or “at least one of A and B”) refers to implementations including any of: (a) at least one A; (b) at least one B; and (c) at least one A and at least one B.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin”, “ball” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

The techniques described in this disclosure may also be embodied or encoded in an article of manufacture including a non-transitory computer-readable storage medium. Example non-transitory computer-readable storage media may include random access memory (RAM), read-only memory (ROM), programmable ROM, erasable programmable ROM, electronically erasable programmable ROM, flash memory, a solid-state drive, a hard disk, magnetic media, optical media, or any other computer readable storage devices or tangible computer readable media. The term “non-transitory” may indicate that the storage medium is not embodied in a carrier wave or a propagated signal. In certain examples, a non-transitory storage medium may store data that can, over time, change (e.g., in RAM or cache).

While the use of particular transistors are described herein, other transistors (or equivalent devices) may be used instead with little or no change to the remaining circuitry. For example, a metal-oxide-silicon FET (“MOSFET”) (such as an n-channel MOSFET, nMOSFET, or a p-channel MOSFET, pMOSFET), a bipolar junction transistor (BJT—e.g. NPN or PNP), insulated gate bipolar transistors (IGBTs), and/or junction field effect transistor (JFET) may be used in place of or in conjunction with the devices disclosed herein. The transistors may be depletion mode devices, drain-extended devices, enhancement mode devices, natural transistors or other type of device structure transistors. Furthermore, the devices may be implemented in/over a silicon substrate (Si), a silicon carbide substrate (SiC), a gallium nitride substrate (GaN) or a gallium arsenide substrate (GaAs).

Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples may be included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means+/−10 percent of the stated value, or, if the value is zero, a reasonable range of values around zero.

Modifications are possible in the described examples, and other examples are possible, within the scope of the claims.

What is claimed is:

1. A circuit comprising:
a differential to single ended (DSE) circuit having a first input, a second input, a first output, and a second output;
a first transistor having first, second, and control terminals, the control terminal of the first transistor coupled to the first output of the DSE circuit;
a second transistor having first, second, and control terminals, the control terminal of the second transistor coupled to the second output of the DSE circuit;
a third transistor having first, second, and control terminals, the first terminal of the third transistor coupled to the first terminal of the first transistor and the control terminal of the third transistor coupled to the first terminal of the second transistor; and
a fourth transistor having first, second, and control terminals, the first terminal of the fourth transistor coupled to the first terminal of the second transistor, and the control terminal of the fourth transistor coupled to the first terminal of the first transistor.

2. The circuit of claim 1 further comprising:
a first inverter having an input and an output, the input of the first inverter coupled to the first terminal of the first transistor and the first terminal of the third transistor;
a second inverter having an input and an output, the input of the second inverter coupled to the output of the first inverter;
a third inverter having an input and an output, the input of the second inverter coupled to the first terminal of the second transistor and the first terminal of the fourth transistor; and
a fourth inverter having an input and an output, the input of the fourth inverter coupled to the output of the third inverter.

3. The circuit of claim 1, further comprising:
a first inverter having an input and an output, the input of the first inverter coupled to the first terminal of the first transistor and the first terminal of the third transistor, and the output of the first inverter coupled to the control terminal of the fourth transistor; and
a second inverter having an input and an output, the input of the second inverter coupled to the first terminal of the second transistor and the first terminal of the fourth transistor, and the output of the second inverter coupled to the control terminal of the third transistor.

4. The circuit of claim 3, further comprising:
a first capacitor having a first terminal and a second terminal, the first terminal of the first capacitor coupled to the output of the first inverter and the control terminal of the fourth transistor; and
a second capacitor having a first terminal and a second terminal, the first terminal of the second capacitor coupled to the output of the second inverter and the control terminal of the third transistor.

5. The circuit of claim 3,
wherein the first inverter includes a fifth transistor having first, second, and control terminals, the control terminal of the fifth transistor coupled to the input of the first inverter and the first terminal of the fifth transistor coupled to the output of the first inverter; and
wherein the second inverter includes a sixth transistor having first, second, and control terminals, the control terminal of the sixth transistor coupled to the input of the second inverter and the first terminal of the sixth transistor coupled to the output of the second inverter.

6. The circuit of claim 5,
wherein width and length parameters of the fifth transistor are selected responsive to a discharge time of a bias signal of the control terminal of the fourth transistor; and
wherein width and length parameters of the sixth transistor are selected responsive to a discharge time of a bias signal of the control terminal of the third transistor.

7. The circuit of claim 1, further comprising a resistor having a first terminal and a second terminal, the first terminal of the resistor coupled to a bias voltage terminal, and the second terminal of the resistor coupled to the control terminals of the first and second transistors.

8. The circuit of claim 7, further comprising:
a first capacitor having a first terminal and a second terminal; and
a second capacitor having a first terminal and a second terminal, the first terminal of the first capacitor coupled to the first output of the DSE circuit, the second terminal of the first capacitor coupled to the control terminals of the first and second transistors and to the second terminal of the second capacitor, and the first terminal of the second capacitor coupled to the second output of the DSE circuit.

9. The circuit of claim 1, wherein the DSE circuit includes:
a fifth transistor having first, second, and control terminals, the first terminal of the fifth transistor coupled to the control terminal of the first transistor;
a sixth transistor having first, second, and control terminals, the first terminal of the sixth transistor coupled to the control terminal of the second transistor;
a first capacitor having a first terminal and a second terminal; and
a second capacitor having a first terminal and a second terminal, the second terminal of the first capacitor coupled to the control terminals of the fifth and sixth transistors and the second terminal of the second capacitor.

10. The circuit of claim 9, wherein the DSE circuit includes:
first and second resistors each having a first terminal and a second terminal;
a third capacitor having a first terminal and a second terminal, the first terminal of the third capacitor coupled to the first terminal of the first capacitor, and the second terminal of the third capacitor coupled to the first terminal of the first resistor and the second terminal of the sixth transistor;
a fourth capacitor having a first terminal and a second terminal, the first terminal of the fourth capacitor coupled to the first terminal of the second capacitor, and the second terminal of the fourth capacitor coupled to the first terminal of the second resistor and the second terminal of the fifth transistor.

11. The circuit of claim 1, further comprising:
a first inverter having an input and an output, the input of the first inverter coupled to the first terminal of the first transistor and the first terminal of the third transistor;
a second inverter having an input and an output, the input of the second inverter coupled to the output of the first inverter, and the output of the second inverter coupled to the control terminal of the fourth transistor;
a third inverter having an input and an output, the input of the third inverter coupled to the first terminal of the second transistor and the first terminal of the fourth transistor; and
a fourth inverter having an input and an output, the input of the fourth inverter coupled to the output of the third inverter, and the output of the fourth inverter coupled to the control terminal of the third transistor.

12. A circuit comprising:
a first transistor having first, second, and control terminals,
a second transistor having first, second, and control terminals;
a third transistor having first, second, and control terminals, the control terminal of the third transistor coupled to the first terminal of the first transistor;
a fourth transistor having first, second, and control terminals, the control terminal of the fourth transistor coupled to the first terminal of the second transistor;
a fifth transistor having first, second, and control terminals, the control terminal of the fifth transistor coupled to the first terminal of the fourth transistor;
a sixth transistor having first, second, and control terminals, the control terminal of the sixth transistor coupled to the first terminal of the third transistor;
a first inverter having an input and an output, the input of the first inverter coupled to the first terminal of the third transistor and the first terminal of the fifth transistor; and
a second inverter having an input and an output, the input of the second inverter coupled to the first terminal of the fourth transistor and the first terminal of the sixth transistor.

13. The circuit of claim 12, the circuit further comprising an output circuit including a first input, a second input, and an output, the first input of the output circuit coupled to the first terminal of the third transistor and the first terminal of the fifth transistor, and the second input of the output circuit coupled to the first terminal of the fourth transistor and the first terminal of the sixth transistor.

14. The circuit of claim 13, wherein the output circuit includes a latch having a first input, a second input, and an output, the first input of the latch coupled to the first input of the output circuit, and the second input of the latch coupled to the second input of the output circuit.

15. The circuit of claim 13, wherein the output circuit includes:
first, second, third, and fourth buffers, each of the buffers respectively having an input and an output, the input of the second buffer coupled to the output of the first buffer, and the input of the fourth buffer coupled to the output of the third buffer;
a latch having a first input, a second input, and an output;
a first OR gate having a first input, a second input, and an output, the first input of the output circuit coupled to the first input of the first OR gate and the input of the first buffer, the second input of the first OR gate coupled to the output of the second buffer, and the output of the first OR gate coupled to the first input of the latch; and
a second OR gate having a first input, a second input, and an output, the second input of the output circuit coupled to the first input of the second OR gate and the input of the third buffer, the second input of the second OR gate coupled to the output of the fourth buffer, and the output of the second OR gate coupled to the second input of the latch.

16. The circuit of claim 12, further comprising:
a first capacitor having a first terminal and a second terminal, the first terminal of the first capacitor coupled to the control terminal of the first transistor, and the second terminal of the first capacitor coupled to the second terminal of the second transistor; and
a second capacitor having a first terminal and a second terminal, the first terminal of the second capacitor coupled to the control terminal of the second transistor, and the second terminal of the second capacitor coupled to the second terminal of the first transistor.

17. The circuit of claim 12, further comprising:
a first capacitor having a first terminal and a second terminal, the first terminal of the first capacitor coupled to the output of the first inverter and the control terminal of the sixth transistor; and
a second capacitor having a first terminal and a second terminal, the first terminal of the second capacitor coupled to the output of the second inverter and the control terminal of the fifth transistor.

18. An apparatus comprising:
a transformer including a primary winding, a secondary winding, and an isolation barrier, the secondary winding having a first terminal and a second terminal;
a transmitter coupled to the primary winding; and
a receiver coupled to the secondary winding, the receiver including:
a differential to single ended (DSE) circuit having a first input, a second input, a first output, and a second output, the first input of the DSE circuit coupled to the first terminal of the secondary winding, the second input of the DSE circuit coupled to the second terminal of the secondary winding;
a first transistor having first, second, and control terminals, the control terminal of the first transistor coupled to the first output of the DSE circuit;
a second transistor having first, second, and control terminals, the control terminal of the second transistor coupled to the second output of the DSE circuit;
a third transistor having first, second, and control terminals;
a fourth transistor having first, second, and control terminals;
a first inverter having an input and an output, the input of the first inverter coupled to the first terminal of the first transistor and the first terminal of the third transistor;
a second inverter having an input and an output, the input of the second inverter coupled to the first terminal of the second transistor and the first terminal of the fourth transistor;
a first capacitor having a first terminal and a second terminal, the first terminal of the first capacitor coupled to the output of the first inverter and the control terminal of the fourth transistor; and
a second capacitor having a first terminal and a second terminal, the first terminal of the second capacitor coupled to the output of the second inverter and the control terminal of the third transistor.

19. The apparatus of claim 18, further comprising:
a third inverter having an input and an output, the input of the third inverter coupled to the first terminal of the first transistor and the first terminal of the third transistor;
a fourth inverter having an input and an output, the output of the third inverter coupled to the input of the first inverter and the input of the fourth inverter;
a fifth inverter having an input and an output, the input of the fifth inverter coupled to the first terminal of the second transistor and the first terminal of the fourth transistor;
a sixth inverter having an input and an output, the output of the fifth inverter coupled to the input of the second inverter and the input of the sixth inverter.

20. The apparatus of claim 19,
a fifth transistor having first, second, and control terminals;
a sixth transistor having first, second, and control terminals;
a first current source having first and second terminals, the first terminal of the first current source coupled to the first terminal of the fifth transistor, the input of the first inverter, the first terminal of the first transistor, and the first terminal of the third transistor;
a second current source having first and second terminals, the first terminal of the second current source coupled to the second terminal of the fifth transistor;
a third current source having first and second terminals, the first terminal of the third current source coupled to the first terminal of the sixth transistor, the input of the second inverter, the first terminal of the second transistor, and the first terminal of the fourth transistor; and
a fourth current source having first and second terminals, the first terminal of the fourth current source coupled to the second terminal of the sixth transistor.
